(19) United States
(12) Patent Application Publication
(10) Pub. No.: US 2025/0255167 A1
(43) Pub. Date: Aug. 7, 2025

(54) DEPOSITION EQUIPMENT FOR DISPLAY DEVICES AND METHOD OF FABRICATING DISPLAY DEVICE USING THE SAME

(71) Applicant: Samsung Display Co., LTD., Yongin-si (KR)

(72) Inventor: Min Goo KANG, Yongin-si (KR)

(21) Appl. No.: 18/924,151

(22) Filed: Oct. 23, 2024

(30) Foreign Application Priority Data
Feb. 1, 2024 (KR) 10-2024-0016258

(51) Int. Cl. H10K 71/16; C23C 14/04; C23C 14/12; C23C 14/24; C23C 14/50

(52) U.S. Cl. CPC H10K 71/166; C23C 14/042; C23C 14/12; C23C 14/24; C23C 14/50; H10K 71/164

(57) ABSTRACT

Deposition equipment for a display device that can improve adhesion between edges of a mask and a substrate, includes a support plate, a mask on a center of the support plate, a holder disposed on an edge of the support plate to support the substrate, a clamp disposed on the holder to be in line with the edge of the support plate, an electrostatic chuck disposed on the holder and having a first avoidance hole disposed in line with the clamp and a magnetic force provider disposed on the electrostatic chuck and having a second avoidance hole disposed in line with the clamp, wherein the clamp includes at least one auxiliary magnet disposed to overlap with the edge of the support plate.

This application claims priority to Korean Patent Application No. 10-2024-0016258, filed on Feb. 1, 2024, and all the benefits accruing therefrom under 35 U.S.C. § 119, the content of which in its entirety is herein incorporated by reference.

### BACKGROUND

### 1. Field

The present invention relates to deposition equipment for a display device, and more particularly, to deposition equipment for a display device that can improve adhesion between edges of a mask and a substrate, and a method of fabricating a display device using the same.

### 2. Description of the Related Art

An organic light-emitting diode display, unlike a liquid-crystal display, is self-luminous. Accordingly, an organic light-emitting diode display does not require a separate light source and thus can be made lighter and thinner. In addition, an organic light-emitting diode display may have high-quality characteristics such as low power consumption, high luminance and fast response speed.

### SUMMARY

Aspects of the invention provide deposition equipment for a display device that can improve adhesion between edges of a mask and a substrate, and a method of fabricating a display device using the same.

According to an embodiment, deposition equipment for a display device includes a support plate, a mask on a center of the support plate, a holder disposed on an edge of the support plate to support the substrate, a clamp disposed on the holder to be in line with the edge of the support plate, an electrostatic chuck disposed on the holder and having a first avoidance hole in line with the clamp and a magnetic force provider disposed on the electrostatic chuck and having a second avoidance hole in line with the clamp, wherein the clamp includes at least one auxiliary magnet disposed to overlap with the edge of the support plate.

In an embodiment, the clamp includes a first base plate wherein the auxiliary magnet is disposed on the first base plate to overlap with the edge of the support plate.

In an embodiment, the first base plate has an insertion groove into which the auxiliary magnet is inserted.

In an embodiment, the magnetic force provider includes at least one main magnet.

In an embodiment, the magnetic force provider includes a second base plate having the second avoidance hole disposed at an edge of the second base plate, wherein the main magnet is disposed on a lower side of the second base plate.

In an embodiment, the mask includes a plurality of subsidiary masks arranged in a second direction, wherein the second base plate has a plurality of second avoidance holes, and wherein the clamp is arranged to be in line with the second avoidance holes that are facing each other in a first direction to be intersecting the second direction when viewed from the top.

In an embodiment, the clamp is also disposed in line with the second avoidance holes to be facing each other in the first direction.

In an embodiment, the at least one main magnet includes a plurality of main magnets, and the at least one auxiliary magnet includes a plurality of auxiliary magnets, and wherein a spacing between adjacent main magnets is equal to a spacing between adjacent auxiliary magnets.

In an embodiment, a spacing between the main magnet and the auxiliary magnet disposed adjacent to each other is equal to the spacing between adjacent main magnets.

In an embodiment, the clamp is able to be lifted up and down between the holder and the magnetic force provider.

In an embodiment, the support plate has an avoidance groove disposed at the edge of the support plate.

In an embodiment, the avoidance groove, the first avoidance hole and the second avoidance hole are arranged to be in line with one another.

In an embodiment, each of the avoidance groove, the first avoidance hole and the second avoidance hole has a U-shape when viewed from the top.

In an embodiment, the support plate has an opening in its center.

In an embodiment, the deposition equipment further includes a deposition source disposed under the support plate.

In an embodiment, the deposition equipment further includes a chamber in which the deposition source, the support plate, the mask, the holder, the clamp, the electrostatic chuck and the magnetic force provider are disposed.

In an embodiment, the auxiliary magnet includes a permanent magnet.

According to an embodiment, a method of fabricating a display device includes preparing deposition equipment for a display device, wherein the deposition equipment includes a deposition source, a support plate disposed above the deposition source, a mask disposed on a center of the support plate, a holder disposed at an edge of the support plate, a clamp disposed on the holder to be in line with the edge of the support plate and including an auxiliary magnet disposed to be in line with the edge of the support plate, an electrostatic chuck disposed on the holder and having a first avoidance hole disposed in line with the clamp and a magnetic force provider disposed on the electrostatic chuck and having a second avoidance hole disposed in line with the clamp, placing a substrate on the holder, lowering the clamp to bring the clamp into contact with the substrate, lowering the electrostatic chuck to attach the substrate to the electrostatic chuck, lowering the holder and raising the clamp, lowering the electrostatic chuck having the substrate attached thereto to bring the substrate into contact with the mask and lowering the magnetic force provider and the clamp together toward the electrostatic chuck.

In an embodiment, raising the clamp includes moving the clamp so that the main magnet of the magnetic force provider and the auxiliary magnet of the clamp are aligned in a direction.

In an embodiment, an upper surface of the main magnet and an upper surface of the auxiliary magnet are aligned in the direction.

In an embodiment, the method of fabricating a display device further includes, after the lowering the magnetic force provider and the clamp together toward the electrostatic chuck, further lowering the clamp to be located below the magnetic force provider.

In an embodiment, a lower surface of the main magnet of the magnetic force provider and an upper surface of the auxiliary magnet are aligned in the direction.

In an embodiment, lowering the holder includes placing the holder in an avoidance hole of the support plate.

In an embodiment, the method of fabricating a display device further includes providing a deposition material from the deposition source to the substrate through the mask.

According to an embodiment, adhesion between the edges of the mask and the substrate can be enhanced.

### BRIEF DESCRIPTION OF THE DRAWINGS

The above and other aspects and features of the present invention will become more apparent by describing in detail exemplary embodiments thereof with reference to the attached drawings, in which:

FIG. 1 is a cross-sectional view of deposition equipment for a display device, according to an embodiment.

FIG. 2 is a plan view of the support plate of FIG. 1, according to an embodiment.

FIG. 3 is a plan view of the support plate and a mask of FIG. 1, according to an embodiment.

FIG. 4 is a plan view of an electrostatic chuck of FIG. 1, according to an embodiment.

FIG. 5 is a plan view of the magnet force provider of FIG. 1, according to an embodiment.

FIG. 6 is a plan view of an example of the magnetic force provider and the clamps of FIG. 1, according to an embodiment.

FIG. 7 is a view for illustrating a method of fabricating a display device using deposition equipment, according to an embodiment.

FIG. 8 is a view for illustrating a method of fabricating a display device using deposition equipment, according to an embodiment.

FIG. 9 is a view for illustrating a method of fabricating a display device using deposition equipment, according to an embodiment.

FIG. 10 is a view for illustrating a method of fabricating a display device using deposition equipment, according to an embodiment.

FIG. 11 is a view for illustrating a method of fabricating a display device using deposition equipment, according to an embodiment.

FIG. 12 is a view for illustrating a method of fabricating a display device using deposition equipment, according to an embodiment.

FIG. 13 is an enlarged view of area A1 of FIG. 12, showing the distribution of magnetic force in area A1, according to an embodiment.

FIG. 14 is a view for illustrating a method of fabricating a display device using deposition equipment, according to an embodiment.

FIG. 15 is an enlarged view of area A2 of FIG. 14, showing the distribution of magnetic force in area A2, according to an embodiment.

FIG. 16 is a plan view of an example of the magnetic force provider and the clamps of FIG. 1, according to an embodiment.

FIG. 17 is a cross-sectional view of deposition equipment for a display device, according to an embodiment.

FIG. 18 is a side view of deposition equipment for a display device for illustrating the operations of the electrostatic chuck and the magnetic force provider, according to an embodiment.

### DETAILED DESCRIPTION

The present invention will now be described more fully hereinafter with reference to the accompanying drawings, in which embodiments of the invention are shown. This invention may, however, be embodied in different forms and should not be construed as being limited to the embodiments set forth herein. Rather, these embodiments are provided so that this disclosure will be thorough and complete, and will fully convey the scope of the invention to those skilled in the art.

It will also be understood that when a layer is referred to as being located “on” another layer or substrate, it can be located directly on the other layer or substrate, or intervening layers may also be present. The same reference numbers indicate the same components throughout the specification. In the attached figures, the thickness of layers and regions are exaggerated for clarity.

Although the terms “first”, “second”, etc. may be used herein to describe various elements, these elements, should not be limited by these terms. These terms may be used to distinguish one element from another element. Thus, a first element discussed below may be termed a second element without departing from teachings of one or more embodiments. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

It will also be understood that when a layer is referred to as being disposed “on”, “connected to” or “coupled to” another element, layer or substrate, it can be directly on the other element, layer or substrate, or intervening elements, layers or substrates may also be present. Likewise, those referred to as “Below”, “Left”, and “Right” include cases where they are directly adjacent to other elements or cases where another layer or other material is interposed. To this end, the term “connected” may refer to physical, electrical, and/or fluid connection, with or without intervening elements.

Unless otherwise specified, the illustrated embodiments are to be understood as providing features of varying detail of some ways in which the disclosure may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

Features of various embodiments of the invention may be combined partially or totally. As will be clearly appreciated by those skilled in the art, technically various interactions and operations are possible. Various embodiments can be practiced individually or in combination.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

Further, the X-axis, the Y-axis, and the Z-axis are not limited to three axes of a rectangular coordinate system, and thus the X-, Y-, and Z-axes, and may be interpreted in a broader sense. For example, the X-axis, the Y-axis, and the Z-axis may be perpendicular to one another, or may represent different directions that are not perpendicular to one another.

For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, ZZ, or the like. As used herein, the term “and/or” includes any and all combinations of one or more of the associated listed items.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature, and the shapes of these regions may not reflect actual shapes of regions of a device and, as such, are not intended to be limiting.

As customary in the field, some embodiments are described and illustrated in the accompanying drawings in terms of functional blocks, units, parts, and/or modules. Those skilled in the art will appreciate that these blocks, units, parts, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, parts, and/or modules being implemented by microprocessors or other similar hardware, they may be programmed and controlled using software (e.g., microcode) to perform various functions discussed herein and may optionally be driven by firmware and/or software. It is also contemplated that each block, unit, part, and/or module may be implemented by dedicated hardware, or as a combination of dedicated hardware to perform some functions and a processor (e.g., one or more programmed microprocessors and associated circuitry) to perform other functions. Also, each block, unit, part, and/or module of some embodiments may be physically separated into two or more interacting and discrete blocks, units, parts, and/or modules without departing from the scope of the invention. Further, the blocks, units, parts, and/or modules of some embodiments may be physically combined into more complex blocks, units, parts, and/or modules without departing from the scope of the invention.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Hereinafter, embodiments of the invention will be described in detail with reference to the accompanying drawings.

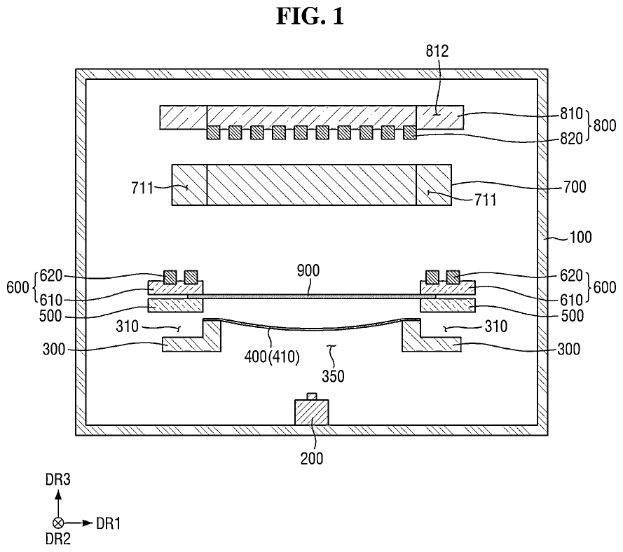

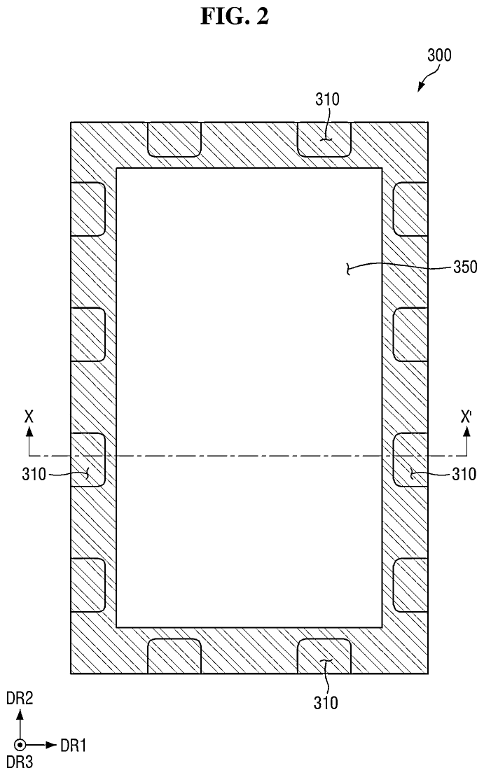

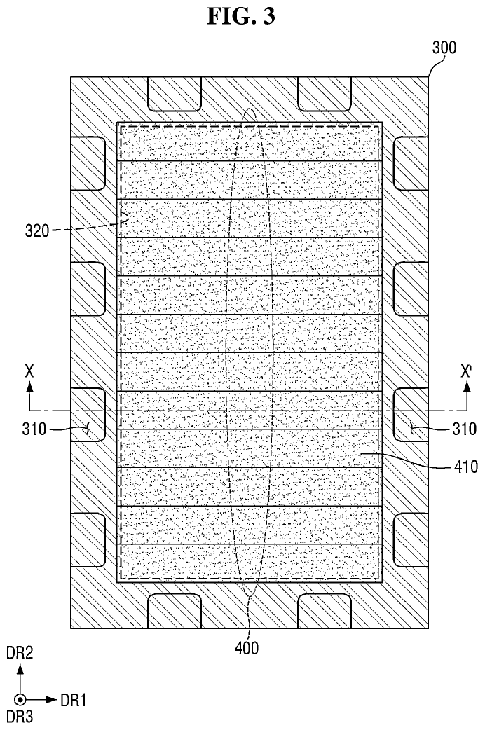

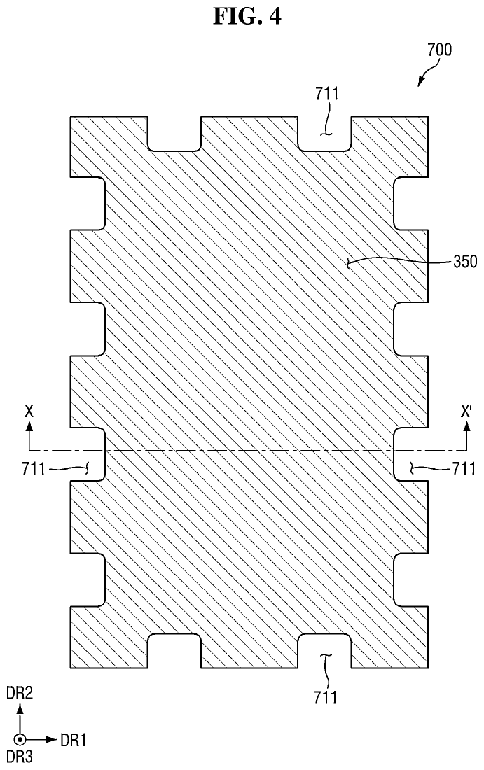

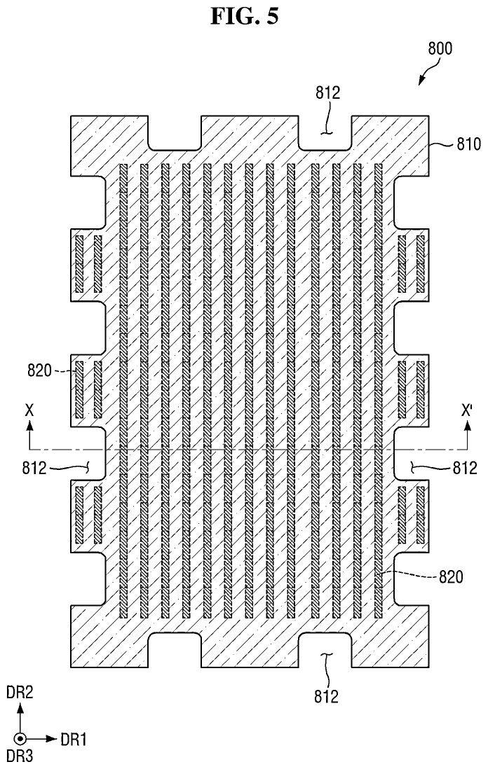

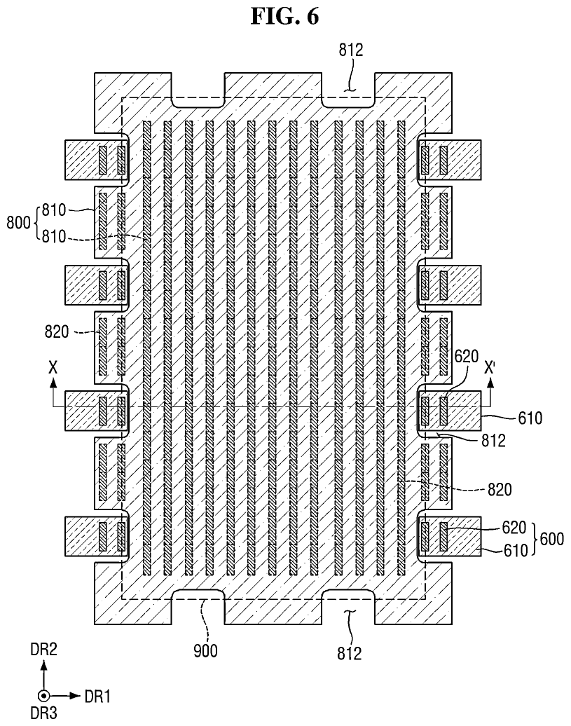

FIG. 1 is a cross-sectional view of deposition equipment for a display device, according to an embodiment. FIG. 2 is a plan view of a support plate 300 of FIG. 1, according to an embodiment. FIG. 3 is a plan view of the support plate 300 and mask 400 of FIG. 1, according to an embodiment. FIG. 4 is a plan view of an electrostatic chuck 700 of FIG. 1, according to an embodiment. FIG. 5 is a plan view of a magnetic force provider 800 of FIG. 1, according to an embodiment. FIG. 6 is a plan view of an example of the magnetic force provider 800 and clamps 600 of FIG. 1, according to an embodiment.

In an embodiment and as shown in FIG. 1, the deposition equipment for a display device may include a chamber 100, a deposition source 200, a support plate 300, a mask 400, a holder 500, a clamp 600, an electrostatic chuck 700, and a magnetic force provider 800. It should be appreciated that the cross-sectional view of the support plate 300 in FIG. 1 may be a cross-sectional view of the support plate 300 taken along the line X-X′ in FIG. 2, the cross-sectional view of the mask 400 in FIG. 1 may be a cross-sectional view of the mask 400 taken along the line X-X′ in FIG. 3, the cross-sectional view of the electrostatic chuck 700 in FIG. 1 may be a cross-sectional view of the electrostatic chuck 700 taken along the line X-X′ in FIG. 4, the cross-sectional view of the magnetic force provider 800 in FIG. 1 may be a cross-sectional view of the magnetic force provider 800 taken along the line X-X′ in FIG. 5, the cross-sectional view of the clamp 600 in FIG. 1 may be a cross-sectional view of the clamp 600 taken along the line X-X′ in FIG. 6 and the cross-sectional view of the substrate 900 in FIG. 1 may be a cross-sectional view of the substrate 900 taken along the line X-X′ in FIG. 6.

The chamber 100 may define a deposition space where a deposition process is carried out, such as for example, a film deposition process for fabricating an organic light-emitting display device may be carried out inside the chamber 100. The chamber 100 may be a vacuum chamber.

The deposition source 200 may be placed under the mask 400. Specifically, the deposition source 200 may be disposed between the mask 400 and the bottom of the chamber 100, where the deposition source 200 may provide a deposition material. The deposition material from the deposition source 200 may move toward the mask 400. Specifically, as the deposition source 200 evaporates the deposition material, such as organic material and electrode material, by heating them at a high temperature, the evaporated deposition material may be deposited onto the substrate 900 through the pattern holes of the mask 400. The above-described organic material may be, for example, the material for producing a hole injection layer, a hole transport layer, an emissive layer, an electron transport layer and an electron injection layer disposed between an anode electrode and a cathode electrode of an organic electroluminescent device. The substrate 900 may be, for example, a substrate which is used in a display device including organic light-emitting diodes.

The support plate 300 may be disposed above the deposition source 200 and may be used to support the mask 400. The support plate 300 may include an opening 350 and a plurality of avoidance grooves 310.

The opening 350 may penetrate the center of the support plate 300 in the third direction DR3. In other words, the support plate 300 may have the shape of a closed curve (or ring) that surrounds the opening 350 and that defines the opening 350. For example, in an embodiment, the support plate 300 may have the shape of a rectangular frame.

The support plate 300 may include a plurality of avoidance grooves 310 formed at the edges of the support plate 300. The avoidance grooves 310 may have a depressed shape directed toward the bottom of the chamber 100. For example, each of the avoidance grooves 310 may have a depressed shape directed in the opposite direction to the third direction DR3 (hereinafter referred to as the third opposite direction). Accordingly, the support plate 300 may have a smaller height where the avoidance grooves 310 are formed. In other words, the height of the support plate 300 may be lower where the avoidance grooves 310 are formed than in other areas thereof (e.g., the remaining area of the support plate 300 excluding the area where the avoidance grooves 310 of the support plate 300 are formed).

The mask 400 may be disposed on the support plate 300. For example, the mask 400 may be disposed on the support plate 300 except on the area of the support plate where the above-described avoidance grooves 310 are formed. The mask 400 may be disposed on the support plate 300 to cover the opening 350 of the support plate 300, where the edges of the mask 400 may be attached to the support plate 300. For example, the mask 400 may be attached to the support plate 300 by welding. Additionally, the mask 400 may be a fine metal mask (FMM).

The mask 400 may include a plurality of subsidiary masks 410 (or mask sticks), as shown in the example of FIG. 3, where each of the subsidiary masks 410 may have a rectangular shape that extend in the first direction DR1. The plurality of subsidiary masks 410 may be arranged in the second direction DR2, where adjacent subsidiary masks 410 may be in contact with each other. A portion of each of the subsidiary masks 410 excluding both of the edges may be located on the opening 350 of the support plate 300. Although not shown in the drawings, each of the plurality of subsidiary masks 410 may have a plurality of pattern holes penetrating the subsidiary masks 410 in the third direction DR3. As such, during the deposition process the deposition material from the deposition source 200 may be deposited onto the substrate 900 through the plurality of pattern holes of each of the subsidiary masks 410. Each of the subsidiary masks 410 may be made of a material containing metal.

Each of the subsidiary masks 410 may sag in the direction of gravity (e.g., the third opposite direction), as shown in FIG. 1. For example, each of the subsidiary masks 410 may have a curved cross-section bent in a convex shape toward the deposition source 200.

The holder 500 may be disposed above the support plate 300 inside the chamber 100 and may be able to be lifted up and down. For example, the holder 500 may move in the third direction DR3 and/or the third opposite direction. The holder 500 may be disposed within the avoidance grooves 310 of the support plate 300 described above. The substrate 900 may be placed on the holder 500, where the edges of the substrate 900 may be supported by the holder 500 and the holder 500 may move the substrate 900 that is disposed on the holder 500 in the third direction DR3 and/or in the third opposite direction.

The clamps 600 may be disposed on the holder 500. For example, the clamps 600 may be disposed on the holder 500 to face the holder 500 in the third opposite direction with the substrate 900 interposed therebetween. The clamps 600 may fix the substrate 900 onto the holder 500 so that the substrate 900 does not move. For example, the clamps 600 may fix the substrate 900 between the holder 500 and the clamp 600 by pressing the substrate 900 in the third opposite direction.

According to an embodiment, each of the clamps 600 may include a first base plate 610 and at least one magnet 620 (hereinafter referred to as an auxiliary magnet 620) disposed on the first base plate 610. For example, the auxiliary magnets 620 may be disposed on the first base plates 610. Specifically, a surface of the first base plate 610 facing the holder 500 may be defined as the lower surface, and the opposite surface of the first base plate 610 may be defined as the upper surface. The auxiliary magnet 620 may be disposed on the upper surface of the first base plate 610.

According to an embodiment, the upper surface of the first base plate 610 may have insertion grooves, and the above-described auxiliary magnets 620 may be disposed within the insertion grooves. In the embodiment shown in FIG. 1, two auxiliary magnets 620 are arranged to be adjacent to each other on the upper surface of each of the clamps 600. The two auxiliary magnets 620 may be arranged so that the opposite polarities are located adjacent to each other. For example, in an embodiment, one of the two auxiliary magnets 620 that are arranged adjacent to each other may be defined as a first auxiliary magnet 620, while the other one may be defined as a second auxiliary magnet 620. A first lower side of the first auxiliary magnet 620 (e.g., the side of the first auxiliary magnet 620 in contact with the first base plate 610) may be the N-pole of the first auxiliary magnet 620, a first upper side of the first auxiliary magnet 620 (e.g., the opposite side of the first auxiliary magnet 620) may be the S-pole, a second lower side of the second auxiliary magnet 620 (e.g., the side of the second auxiliary magnet 620 in contact with the first base plate 610) may be the S-pole, and a second upper side of the second auxiliary magnet 620 (e.g., the opposite side of the second auxiliary magnet 620) may be the N-pole. The auxiliary magnets 620 may be, for example, permanent magnets.

The electrostatic chuck 700 may be placed above the clamps 600 and may adsorb the substrate 900 with electrostatic force. The electrostatic chuck 700 may be placed inside the chamber 100 and may be able to be lifted up and down. For example, the electrostatic chuck 700 may move along the third direction DR3 and/or the third opposite direction and the center of the substrate 900 may be in contact with the lower surface of the electrostatic chuck 700. The electrostatic chuck 700 may move the substrate 900 that is attached to the lower surface of the electrostatic chuck 700 in the third direction DR3 and/or the third opposite direction. According to an embodiment, as shown in FIG. 4, the electrostatic chuck 700 may have a plurality of first avoidance holes 711 disposed at the edges of the electrostatic chuck 700, where the first avoidance holes 711 may penetrate the electrostatic chuck 700 in the third direction DR3. Each of the first avoidance holes 711 may have a U-shape with one side open when viewed from the top. When at least one of the electrostatic chuck 700 and the clamps 600 is raised or lowered, the clamps 600 may be located in line with the first avoidance holes 711 of the electrostatic chuck 700 so that the clamps 600 and the electrostatic chuck 700 do not interfere with each other along the lifting path. Accordingly, when the clamps 600 disposed under the electrostatic chuck 700 moves in the third direction DR3 toward the upper side of the electrostatic chuck 700, the clamps 600 may move in the third direction DR3 through the first avoidance holes 711. The electrostatic chuck 700 may be made of a material containing ceramic or titanium.

The magnetic force provider 800 may be disposed above the electrostatic chuck 700. For example, the magnetic force provider 800 may be disposed above the electrostatic chuck 700 to face the electrostatic chuck 700, where the magnetic force provider 800 may provide a magnetic force. For example, the magnetic force provider 800 may provide a magnetic force so that the above-described metal mask 400 comes into tight contact with the substrate 900. The magnetic force provider 800 may be placed within the chamber 100 and may be able to be lifted up and down. For example, the magnetic force provider 800 may move in the third direction DR3 and/or the third opposite direction.

According to an embodiment, the magnetic force provider 800 may include a second base plate 810 and a plurality of magnets 820 (hereinafter referred to as main magnets 820) disposed on the second base plate 810. For example, the main magnets 820 may be disposed on the second base plates 810. Specifically, a surface of the second base plate 810 facing the electrostatic chuck 700 may be defined as the lower side and the main magnet 820 may be disposed on the lower side of the second base plate 810. According to an embodiment, the lower side of the second base plate 810 may have insertion grooves, and the above-described main magnets 820 may be inserted into and located within the insertion grooves. In the example shown in FIG. 1, ten main magnets 820 are arranged to be adjacent to one another on the lower side of the magnetic force provider 800. The ten main magnets 620 may be arranged so that the opposite polarities are disposed adjacent to each other. For example, one of the two main magnets 620 arranged to be adjacent to each other may be defined as a first main magnet 820, while the other may be defined as a second main magnet 820. A first upper side of the first main magnet 820 (e.g., the side of the first main magnet 620 in contact with the second base plate 810) may be the N-pole of the first main magnet 820, a first lower side of the first main magnet 820 (e.g., the opposite side of the first main magnet 820) may be the S-pole, a second upper side of the second main magnet 820 (e.g., the side of the second main magnet 620 in contact with the second base plate 810) may be the S-pole, and a second lower side of the second main magnet 820 (e.g., the opposite side of the second main magnet 820) may be the N-pole. The main magnets 820 may be, for example, permanent magnets.

According to an embodiment, as shown in FIG. 5, a plurality of main magnets 820 may be arranged in the second direction DR2. The plurality of main magnets 820 arranged in a row in the second direction DR2 may be defined as a group magnet. A plurality of group magnets may be arranged along the first direction DR1 to be spaced apart from each other. The group magnets disposed adjacent to each other may be arranged so that the opposite polarities are located adjacent to each other. For example, for the first group magnet and the second group magnet which are disposed adjacent to each other, the lower sides of the main magnets 820 included in the first group magnet may be S-poles, while the lower sides of the main magnets 820 included in the second group magnet may be N-poles.

According to an embodiment and as shown in FIG. 6, at least one of the main magnets 820 of the outermost group magnet may be disposed to be adjacent to the auxiliary magnet 620, and thus the main magnets 820 and the auxiliary magnets 620 disposed adjacent to each other may be arranged so that the opposite polarities are located adjacent to each other. For example, for the main magnet 820 and the auxiliary magnet 620 disposed adjacent to each other, the lower side of the main magnet 820 may be the S-pole while the lower side of the auxiliary magnet 620 may be the N-pole.

According to an embodiment, the spacing between adjacent main magnets 820 may be equal to the spacing between adjacent auxiliary magnets 620. For example, as in the embodiment shown in FIG. 6, the spacing between the adjacent main magnets 820 in the first direction DR1 may be defined as a first spacing, and the spacing between adjacent auxiliary magnets 620 in the first direction DR1 may be defined as a second spacing, where the first spacing may be equal to the second spacing.

According to an embodiment, the spacing between the main magnet 820 and the auxiliary magnet 620 disposed adjacent to each other may be equal to the spacing between adjacent main magnets 820. For example, as in the embodiment shown in FIG. 6, the spacing between a main magnet 820 disposed at the outermost position of the second base plate 810 and the auxiliary magnet 620 disposed adjacent to the main magnet 820 in the first direction DR1 may be defined as a third spacing, where the third spacing may be equal to the first spacing (or second spacing) mentioned above.

According to an embodiment, as in the embodiment shown in FIG. 5, the second base plate 810 may have a plurality of second avoidance holes 812 disposed at the edges of the second base plate 810. The second avoidance holes 812 may penetrate the second base plate 810 in the third direction DR3, where each of the second avoidance holes 812 may have a U-shape having one side open when viewed from the top. When at least one of the magnetic force provider 800 and the clamps 600 is raised or lowered, the clamps 600 may be located in line with the second avoidance holes 812 of the magnetic force provider 800 so that the clamps 600 and the magnetic force provider 800 do not interfere with each other on the lifting path. Accordingly, when the clamps 600 disposed under the magnetic force provider 800 moves in the third direction DR3 toward the upper side of the magnetic force provider 800, the clamps 600 may move in the third direction DR3 through the second avoidance holes 812. For example, the clamps 600 may pass through the first avoidance holes 711 of the electrostatic chuck 700 and then the second avoidance holes 812 of the magnetic force provider 800 to move to the upper side of the magnetic force provider 800. According to an embodiment, the first avoidance holes 711 and the second avoidance holes 812 may be arranged to be in line with each other.

According to an embodiment, as shown in FIG. 6, the clamps 600 may be arranged in line with the second avoidance holes 812 facing each other in the first direction DR1 when viewed from the top. For example, as the mask 400 includes a plurality of subsidiary masks 410 arranged in the second direction DR2, the clamps 600 described above may be arranged to be in line with the second avoidance holes 812 facing each other in the first direction DR1 and intersecting the second direction DR2.

According to an embodiment, an additional magnetic force may be exerted to the edges of the mask 400 by the auxiliary magnets 620. As a result, the adhesion between the mask 400 and the substrate 900 at the edges of the mask 400 can be enhanced. Accordingly, the mask 400 and the substrate 900 can be accurately aligned with each other, and thus the deposition material from the deposition source 200 can be accurately deposited on the corresponding deposition area of the substrate 900.

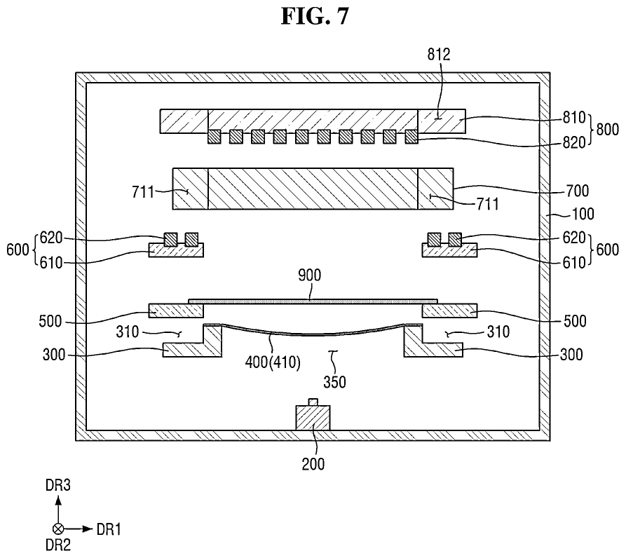

FIGS. 7 to 12 are views for illustrating a method of fabricating a display device using deposition equipment, according to an embodiment.

First, in an embodiment as shown in FIG. 7, a substrate 900 may be disposed on holder 500, where the edges of the lower surface of the substrate 900 may be in contact with the holder 500.

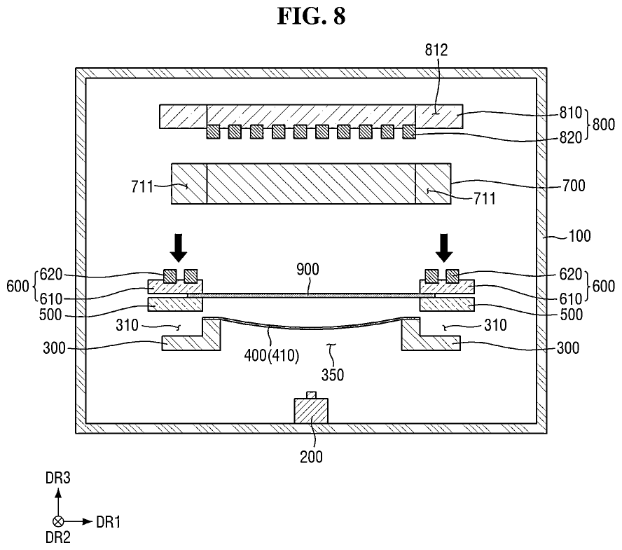

The clamps 600 may then descend in the third opposite direction as shown in FIG. 8. For example, the clamps 600 may descend toward the holders 500 on which the substrate 900 is placed until the clamps 600 come in contact with the substrate 900. Once the clamps 600 are in contact with the substrate 900, the clamps 600 may stop moving.

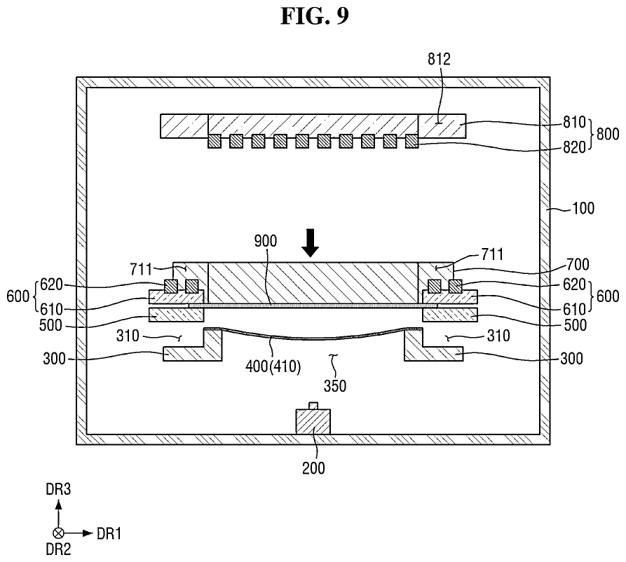

An electrostatic chuck 700 may then descend in the third opposite direction, as shown in FIG. 9. For example, the electrostatic chuck 700 may descend toward the substrate 900 until the electrostatic chuck 700 comes in contact with the substrate 900. Once the electrostatic chuck 700 is in contact with the substrate 900, the electrostatic chuck 700 may stop moving. The substrate 900 may be attached to the lower surface of the electrostatic chuck 700 by the electrostatic force exerted by the electrostatic chuck 700.

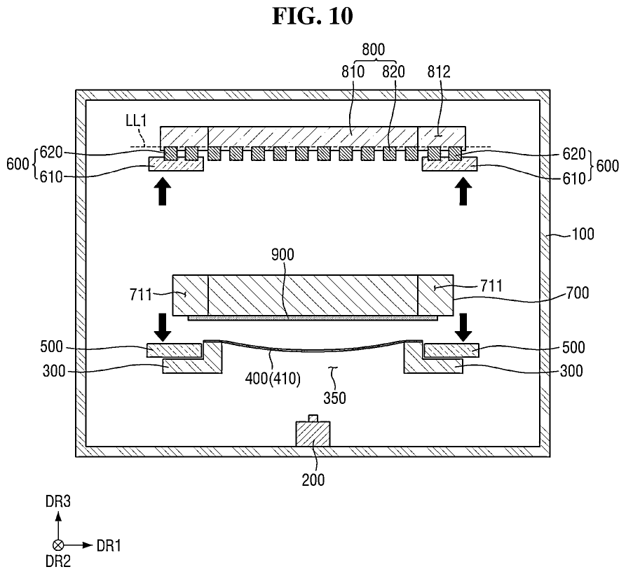

In an embodiment and as shown in FIG. 10, the holder 500 may then descend in the third opposite direction and may be disposed within the avoidance grooves 310 of the support plate 300, and the clamps 600 may rise in the third direction DR3 and may be partially inserted into the second avoidance holes 812 of the magnetic force provider 800. For example, the clamps 600 may move in the third direction DR3, may pass through the first avoidance holes 711 of the electrostatic chuck 700, and then may move further in the third direction DR3 to be partially inserted into the second avoidance holes 812 of the magnetic force provider 800, where the auxiliary magnets 620 of the clamps 600 may be partially disposed within the second avoidance holes 812. At this time, the clamps 600 may move in the third direction DR3 and then stop so that the auxiliary magnets 620 and the main magnets 820 are aligned with each other in the first direction DR1. For example, the clamps 600 may move in the third direction DR3 and then stop so that the upper surfaces of the auxiliary magnets 620 and the upper surfaces of the main magnets 820 are aligned in a row along a virtual line LL1, as shown in FIG. 10.

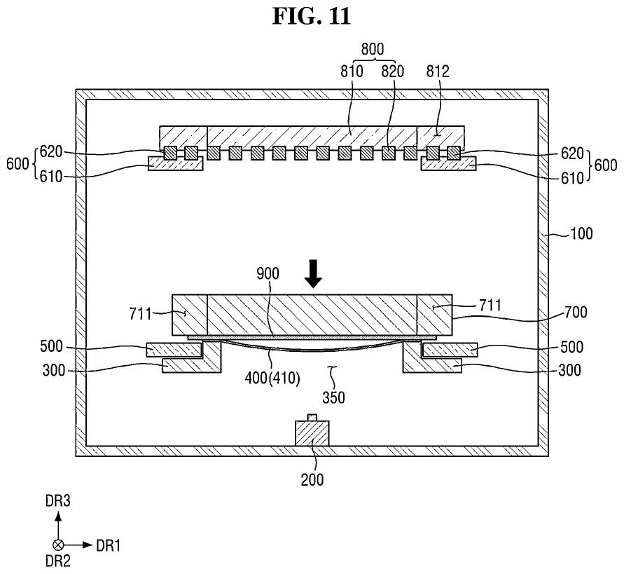

In an embodiment and as shown in FIG. 11, the electrostatic chuck 700 having the substrate 900 attached thereto may further descend in the third opposite direction. For example, the electrostatic chuck 700 may move further in the third opposite direction until the substrate 900 comes in contact with the mask 400. Once the substrate 900 comes in contact with the mask 400, the electrostatic chuck 700 may stop moving, and the edges of the substrate 900 may be in contact with the edges of the mask 400.

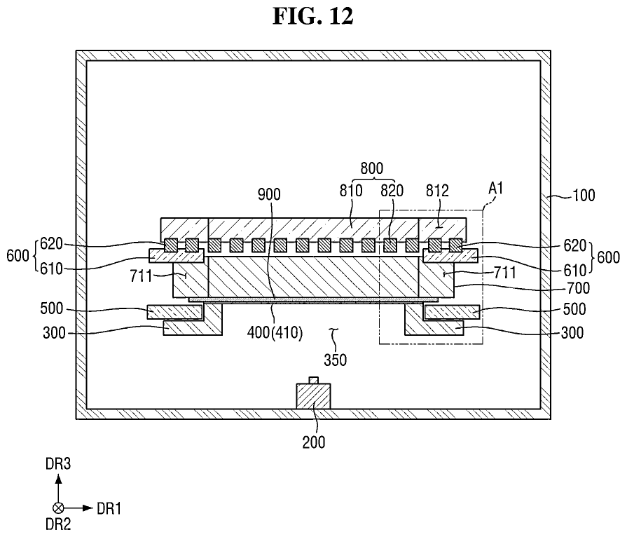

In an embodiment and as shown in FIG. 12, the magnetic force provider 800 and the clamps 600 may descend together in the third opposite direction. For example, while the main magnets 820 and the auxiliary magnets 620 are maintained to be aligned in the first direction DR1, the magnetic force provider 800 and the clamps 600 may descend together in the third opposite direction. The magnetic force provider 800 and the clamps 600 may then be located as close to the electrostatic chuck 700 as possible so that the magnetic force of the main magnets 820 and the auxiliary magnets 620 is sufficiently provided to the mask 400. Once the magnetic force provider 800 and the clamps 600 are located sufficiently close to the electrostatic chuck 700, the magnetic force provider 800 and the clamps 600 may stop moving. By the magnetic force caused by the main magnets 820 of the magnetic force provider 800 and the auxiliary magnets 620 of the clamps 600, the mask 400, which is made of metal, may be attracted toward the main magnets 820 and the auxiliary magnets 620. Accordingly, the mask 400 can come into contact with the substrate 900 strongly. Therefore, the adhesion between the mask 400 and the substrate 900 can be enhanced.

According to an embodiment, as the auxiliary magnets 620 are disposed along the edges of the mask 400, the magnetic force exerted by the auxiliary magnets 620 can be sufficiently provided to the edges of the mask 400. Despite the insufficient number of main magnets 820 at the edges of the magnetic force provider 800 due to the second avoidance holes 812, the edges of the mask 400 can come in strong contact with the substrate 900. As a result, the adhesion between the edges of the mask 400 and the substrate 900 can be enhanced. Accordingly, it is possible to prevent contact failure at the edges of the mask 400.

Subsequently, the deposition material from the deposition source 200 may be deposited on the substrate 900 through the mask 400.

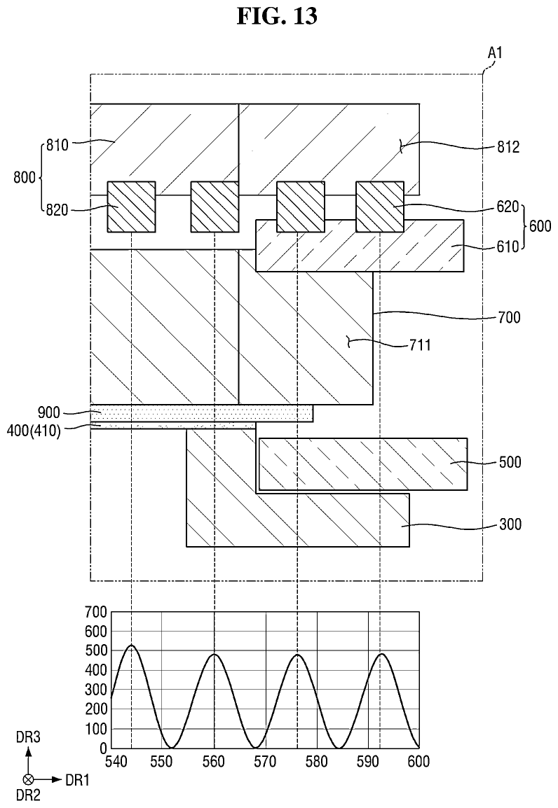

FIG. 13 is an enlarged view of area A1 of FIG. 12, showing the distribution of magnetic force in area A1, according to an embodiment.

In the magnetic force distribution graph of FIG. 13, the x-axis represents the location, and the y-axis represents the strength of the magnetic force.

As shown in FIG. 13, the magnetic force located at an edge of the mask 400 can be increased by the auxiliary magnets 620. Accordingly, the adhesion between the edge of the mask 400 and the substrate 900 can be enhanced.

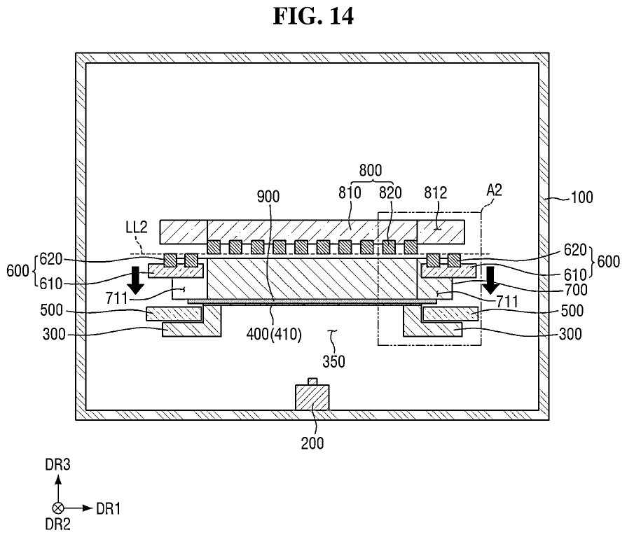

FIG. 14 is a view for illustrating a method of fabricating a display device using deposition equipment, according to an embodiment. For example, the processing step of FIG. 14 may be performed after the processing step of FIG. 12 described above.

In an embodiment and as shown in FIG. 12 described above, after the magnetic force provider 800 and the clamps 600 simultaneously descend in the third opposite direction to approach the electrostatic chuck 700, the clamps 600 may descend further in the third opposite direction as shown in FIG. 14. In other words, the clamps 600 may descend further in the third opposite direction so that the auxiliary magnets 620 are located lower than the main magnets 820. For example, the clamps 600 may move in the third direction DR3 and then stop so that the upper surfaces of the auxiliary magnets 620 and the lower surfaces of the main magnets 820 are aligned in a row along a virtual line LL2.

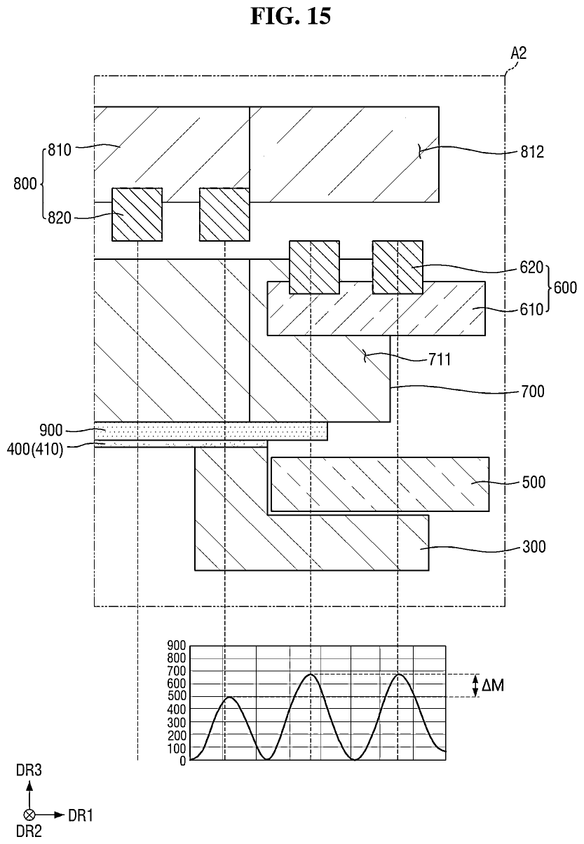

FIG. 15 is an enlarged view of area A2 of FIG. 14, showing the distribution of magnetic force in area A2, according to an embodiment.

In the magnetic force distribution graph of FIG. 15, the x-axis represents the location, and the y-axis represents the strength of the magnetic force.

In an embodiment and as shown in FIG. 15, the magnetic force exerted at the edge of the mask 400 can be further increased by the auxiliary magnets 620 that are disposed lower than the main magnets 820. For example, the magnetic force exerted by the auxiliary magnets 620 at the edge of the mask 400 may be greater than the magnetic force exerted by the main magnets 820 by an amount ΔM. Accordingly, the adhesion between the edge of the mask 400 and the substrate 900 can be further enhanced.

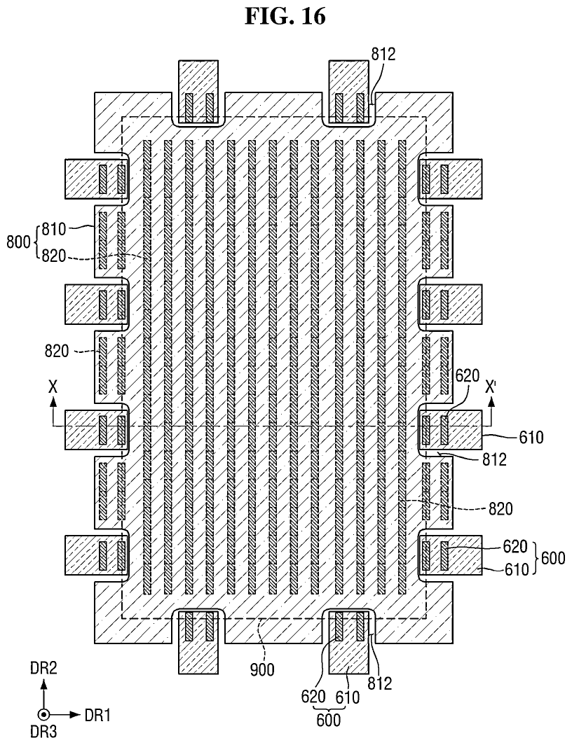

FIG. 16 is a plan view of the magnetic force provider 800 and the clamps 600 of FIG. 1, according to the embodiment.

The clamps 600 of FIG. 16 are different from the clamps 600 of FIG. 6 described above in that they are disposed in all of the second avoidance holes 812 of the magnetic force provider 800. The following description will focus on the difference.

In an embodiment and as shown in FIG. 16, the clamps 600 may be disposed on all of the sides of the magnetic force provider 800 to surround the magnetic force provider 800 when viewed from the top. In other words, the clamps 600 may be disposed in all of the second avoidance holes 812 of the second base plate 810. In this embodiment, the magnetic force located at the edges of the mask 400 can be further increased. Accordingly, the adhesion between the edge of the mask 400 and the substrate 900 can be further enhanced.

For example, as shown in FIG. 16, the clamps 600 may be disposed within the second avoidance holes 812 facing each other in the first direction DR1 as well as the second avoidance holes 812 facing each other in the second direction DR2 when viewed from the top.

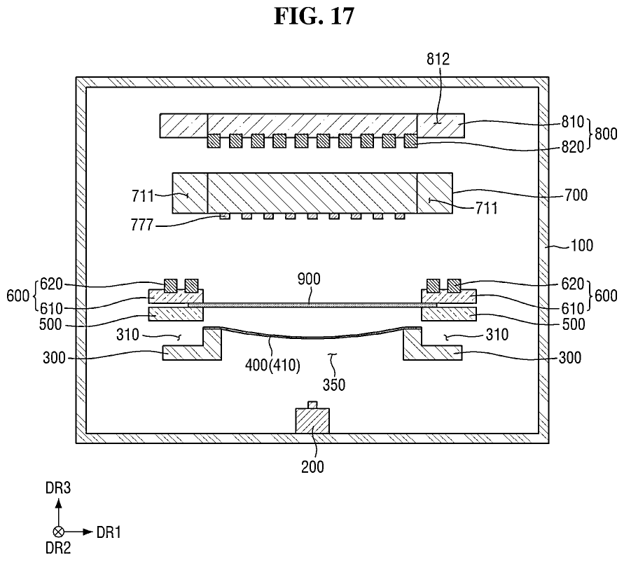

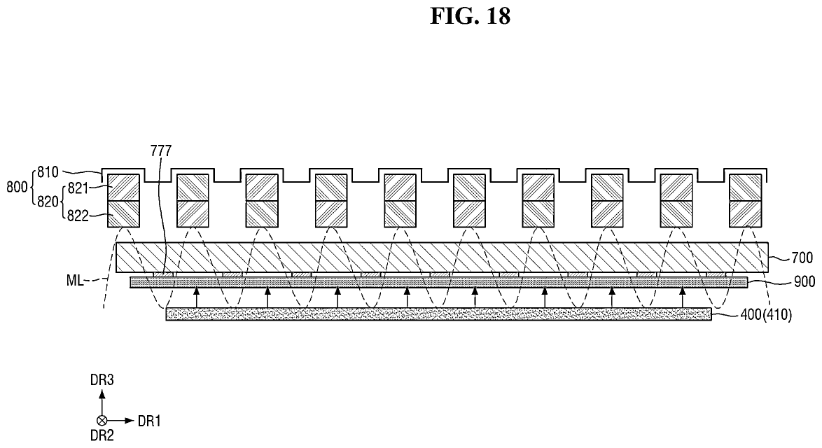

FIG. 17 is a cross-sectional view of deposition equipment for a display device, according to an embodiment. FIG. 18 is a side view of deposition equipment for a display device for illustrating the operations of the electrostatic chuck 700 and the magnetic force provider 800, according to an embodiment.

The deposition equipment for a display device of FIG. 17 is different from the deposition equipment for the display device of FIG. 1 described above. The description will focus on the difference.

In an embodiment and as shown in FIG. 17, the electrostatic chuck 700 may further include a plurality of adsorption electrodes 777 which may be disposed on the lower surface of the electrostatic chuck 700. For example, the plurality of adsorption electrodes 777 may be disposed on the lower surface of the electrostatic chuck 700 to face the substrate 900. The adsorption electrodes 777 may be disposed on the lower surface of the electrostatic chuck 700 so that each of the adsorption electrodes 777 is positioned between every two of the main magnets 820 of the magnetic force provider 800. It should be understood, however, that the invention is not limited thereto. For example, at least one of the adsorption electrodes 777 may be disposed in line with at least one main magnet 820.

Moreover, in an embodiment, power from a power supply unit may be applied to the plurality of adsorption electrodes 777. When power is applied to the plurality of adsorption electrodes 777, the substrate 900 may be adsorbed to the adsorption electrodes 777 of the electrostatic chuck 700 as shown in FIG. 18.

In an embodiment and as shown in FIG. 18, the main magnets 820 of the magnetic force provider 800 may be permanent magnets where each include the N-pole and the S-pole arranged in the third direction DR3. The polarities of the main magnets 820 that disposed adjacent to each other in the first direction DR1 may face the opposite polarities. For example, the N-pole of a main magnet 820 may face the S-pole of another main magnet 820 which is disposed adjacent to it in the first direction, and the S-pole of the main magnet 820 may face the N-pole of the other main magnet 820.

As in the example shown in FIG. 18, a magnetic force, which follows the magnetic force line ML, generated by the main magnets 820 may be provided to the mask 400 through the electrostatic chuck 700. For example, the magnetic force may pass between the plurality of adsorption electrodes 777 of the electrostatic chuck 700 and may be applied to the mask 400. Thus, the mask 400 may be brought into tight contact with the substrate 900 by the magnetic force being applied to the mask 400.

According to an embodiment, the above-described auxiliary magnets 620 may be permanent magnets each including the N-pole and the S-pole arranged in the third direction like the main magnets 820. The polarities of the auxiliary magnets 620 disposed adjacent to each other in the first direction DR1 may face the opposite polarities. For example, the N-pole of an auxiliary magnet 620 may face the S-pole of an adjacent auxiliary magnet 620 in the first direction, and the S-pole of the auxiliary magnet 620 may face the N-pole of another adjacent auxiliary magnet 620. In addition, when the main magnets 820 and the auxiliary magnets 620 are disposed adjacent to each other in the first direction, the polarities of the main magnets 820 and the auxiliary magnets 620 disposed adjacent to each other in the first direction may face the opposite polarities. For example, the N-poles of the main magnets 820 and the S-poles of the auxiliary magnets 620 may face each other in the first direction DR1, and the S-poles of the main magnets 820 and the N-poles of the auxiliary magnets 620 may face each other in the first direction DR1.

In concluding the detailed description, those skilled in the art will appreciate that many variations and modifications can be made to the invention without substantially departing from the scope and principles of the invention. Therefore, the disclosed embodiments of the invention are used in a generic and descriptive sense only and not for purposes of limitation. Each component specifically shown in the embodiments of the invention can be implemented by modification, and such modifications and differences related to application should be construed as being included in the scope of the invention. Moreover, the embodiments or parts of the embodiments may be combined in whole or in part without departing from the scope of the invention.

What is claimed is:

1. A deposition equipment for a display device, the deposition equipment comprising:
a support plate;
a mask disposed on a center of the support plate;
a holder disposed on an edge of the support plate to support a substrate;
a clamp disposed on the holder to be in line with the edge of the support plate;
an electrostatic chuck disposed on the holder and having a first avoidance hole in line with the clamp; and
a magnetic force provider disposed on the electrostatic chuck and having a second avoidance hole in line with the clamp,
wherein the clamp comprises at least one auxiliary magnet disposed to overlap the edge of the support plate.

2. The deposition equipment of claim 1, wherein the clamp further comprises, a first base plate, wherein the at least one auxiliary magnet is disposed on the first base plate to overlap the edge of the support plate.

3. The deposition equipment of claim 2, wherein the first base plate has an insertion groove into which the at least one auxiliary magnet is inserted.

4. The deposition equipment of claim 1, wherein the magnetic force provider comprises at least one main magnet.

5. The deposition equipment of claim 4, wherein the magnetic force provider further comprises,
a second base plate having the second avoidance hole located at an edge of the second base plate; and
the main magnet disposed on a lower side of the second base plate.

6. The deposition equipment of claim 5, wherein the mask comprises a plurality of subsidiary masks arranged in a second direction,
wherein the second base plate has a plurality of second avoidance holes, and
wherein the clamp is arranged in line with the plurality of second avoidance holes which are facing each other in a first direction and which intersects the second direction when viewed from top.

7. The deposition equipment of claim 4, wherein the at least one main magnet comprises a plurality of main magnets, and the at least one auxiliary magnet comprises a plurality of auxiliary magnets, and
wherein a spacing between adjacent main magnets of the plurality of main magnets is equal to a spacing between adjacent auxiliary magnets of the plurality of auxiliary magnets.

8. The deposition equipment of claim 7, wherein a spacing between the plurality of main magnets and the plurality of auxiliary magnets disposed adjacent to each other is equal to the spacing between the adjacent main magnets of the plurality of main magnets.

9. The deposition equipment of claim 1, wherein the clamp is movable in an up and down direction between the holder and the magnetic force provider.

10. The deposition equipment of claim 1, wherein the support plate has an avoidance groove disposed at the edge of the support plate.

11. The deposition equipment of claim 10, wherein the avoidance groove, the first avoidance hole and the second avoidance hole are arranged in line with one another.

12. The deposition equipment of claim 10, wherein each of the avoidance groove, the first avoidance hole and the second avoidance hole has a U-shape when viewed from top.

13. The deposition equipment of claim 1, wherein the support plate has an opening in the center of the support plate.

14. The deposition equipment of claim 1, further comprising:
a deposition source disposed under the support plate.

15. The deposition equipment of claim 14, further comprising:
a chamber in which the deposition source, the support plate, the mask, the holder, the clamp, the electrostatic chuck and the magnetic force provider are disposed.

16. The deposition equipment of claim 1, wherein the at least one auxiliary magnet comprises a permanent magnet.

17. A method of fabricating a display device, the method comprising:
preparing deposition equipment for a display device, the deposition equipment comprising:
a deposition source;
a support plate disposed above the deposition source;
a mask disposed on a center of the support plate;
a holder disposed at an edge of the support plate;
a clamp disposed on the holder to be in line with the edge of the support plate, the clamp comprising,
an auxiliary magnet disposed in line with the edge of the support plate;
an electrostatic chuck disposed on the holder and having a first avoidance hole disposed in line with the clamp; and a magnetic force provider disposed on the electrostatic chuck and having a second avoidance hole disposed in line with the clamp;
placing a substrate on the holder;
lowering the clamp to bring the clamp into contact with the substrate;
lowering the electrostatic chuck to attach the substrate to the electrostatic chuck;
lowering the holder and raising the clamp;
lowering the electrostatic chuck having the substrate attached thereto to bring the substrate into contact with the mask; and
lowering the magnetic force provider and the clamp together toward the electrostatic chuck.

18. The method of claim 17, wherein the raising the clamp comprises, moving the clamp so that a main magnet of the magnetic force provider and an auxiliary magnet of the clamp are aligned in a direction.

19. The method of claim 18, wherein an upper surface of the main magnet and an upper surface of the auxiliary magnet are aligned in the direction.

20. The method of claim 18, further comprising:
after the lowering the magnetic force provider and the clamp together toward the electrostatic chuck,
further lowering the clamp to be disposed below the magnetic force provider.

21. The method of claim 20, wherein a lower surface of the main magnet of the magnetic force provider and an upper surface of the auxiliary magnet are aligned in the direction.

22. The method of claim 17, wherein the lowering the holder comprises:
placing the holder in an avoidance hole of the support plate.

23. The method of claim 17, further comprising:
providing a deposition material from the deposition source to the substrate through the mask.
